(19) United States
(12) Patent Application Publication
(10) Pub. No.: US 2024/0224568 A1
(43) Pub. Date: Jul. 4, 2024

(54) DISPLAY DEVICE

(71) Applicant: LG Display Co., Ltd., Seoul (KR)

(72) Inventors: Yuseop SHIN, Bucheon-si (KR); Dongseok LEE, Bucheon-si (KR); Jusang RHIM, Seoul (KR); Sunghwan YOON, Seoul (KR); Minjae KANG, Seoul (KR); Rokhee LEE, Seoul (KR)

(21) Appl. No.: 18/471,078

(22) Filed: Sep. 20, 2023

(30) Foreign Application Priority Data
Dec. 30, 2022 (KR) 10-2022-0191260

(51) Int. Cl. H10K 50/125; H10K 59/131; H10K 59/35; H10K 59/80

(52) U.S. Cl. CPC H10K 50/125; H10K 59/131; H10K 59/352; H10K 59/8722

(57) ABSTRACT

Disclosed is a display device including a plurality of light-emitting elements having different sizes and assembled to constitute a single pixel, wherein at least two of the light-emitting elements including respective through-holes therein are disposed so as to overlap each other in the single pixel.

### CROSS-REFERENCE TO RELATED APPLICATION

This application claims priority from Korean Patent Application No. 10-2022-0191260 filed on Dec. 30, 2022 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device, and more particularly, to a display device capable of improving integration of a pixel.

### Description of the Related Art

A display device is applied to various electronic devices such as TVs, mobile phones, laptops, and tablets. To this end, research to develop thinning, lightening, and low power consumption of the display device is continuing.

Among display devices, a light-emitting display device has a light-emitting element or a light source built therein and displays information using light generated from the built-in light-emitting element or light source. A display device including a self-light-emitting element may be implemented to be thinner than a display device with the built-in light source, and may be implemented as a flexible display device that may be folded, bent, or rolled.

The display device having the self-light-emitting element may include, for example, an organic light-emitting display device (OLED) including a light-emitting layer made of an organic material, or a micro-LED display device (micro light-emitting diode display device) including a light-emitting layer made of an inorganic material. In this regard, the organic light-emitting display device does not require a separate light source.

### BRIEF SUMMARY

However, the inventors of the present disclosure have recognized the problems that due to material characteristics of the organic material that is vulnerable to moisture and oxygen, a defective pixel easily occurs in the organic light-emitting display device due to an external environment, such as humidity or moisture. On the contrary, the micro-LED display device includes the light-emitting layer made of the inorganic material that is resistant to moisture and oxygen and thus is not affected by the external environment and thus has high reliability and has a long lifespan compared to the organic light-emitting display device.

A technical purpose according to an exemplary embodiment of the present disclosure is to provide a display device capable of improving pixel integration.

Moreover, a technical purpose according to an exemplary embodiment of the present disclosure is to provide a display device in which a small-sized pixel is implemented so as to be applied to a technical field requiring high resolution.

Purposes according to the present disclosure are not limited to the above-mentioned purpose. Other purposes and advantages according to the present disclosure that are not mentioned may be understood based on following descriptions, and may be more clearly understood based on exemplary embodiments according to the present disclosure. Further, it will be easily understood that the purposes and advantages according to the present disclosure may be realized using any features shown in the specification, figures, claimed or combinations thereof.

In the display device according to an exemplary embodiment of the present disclosure, a plurality of light-emitting elements having different sizes may be assembled to constitute one pixel. In one pixel, at least two light-emitting elements including through-holes therein may be disposed so as to overlap each other.

According to an exemplary embodiment of the present disclosure, as one pixel is constituted by assembling the light-emitting elements having the ring shape and having the different sizes so as to overlap each other, the small-sized pixel may be realized, which has the effect of improving the pixel integration within the display device of the same size.

Moreover, as the pixel integration is improved within the display device of the same size, the display device that may be applied in the fields requiring the high resolution may be realized.

Moreover, as the pixel integration is improved within the display device of the same size, the pixel with the high efficiency and the high luminance may be realized even at the low power, which has the effect of reducing the power consumption.

Benefits of the present disclosure are not limited to the effects mentioned above, and other effects not mentioned will be clearly understood by those skilled in the art from the descriptions below.

### BRIEF DESCRIPTION OF THE SEVERAL VIEWS OF THE DRAWINGS

FIG. 1 is a diagram showing a display device according to an exemplary embodiment of the present disclosure.

FIG. 2 to FIG. 4 are diagrams showing a structure of each light-emitting element.

FIG. 5 to FIG. 7 are diagrams for illustrating a method for manufacturing a light-emitting element according to an exemplary embodiment of the present disclosure.

FIG. 8 to FIG. 16 are diagrams for illustrating a method for manufacturing a display device according to an exemplary embodiment of the present disclosure.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same or similar reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc., disclosed in the drawings for illustrating embodiments of the present disclosure are illustrative, and the present disclosure is not limited thereto. The same reference numerals refer to the same elements herein.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “including,” “include,” and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may denote the entire list of elements, may denote the individual elements of the list, or may denote any combination of the elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to,” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first,” “second,” “third,” and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or.’ That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device according to each embodiment of the present disclosure will be described with reference to the accompanying drawings.

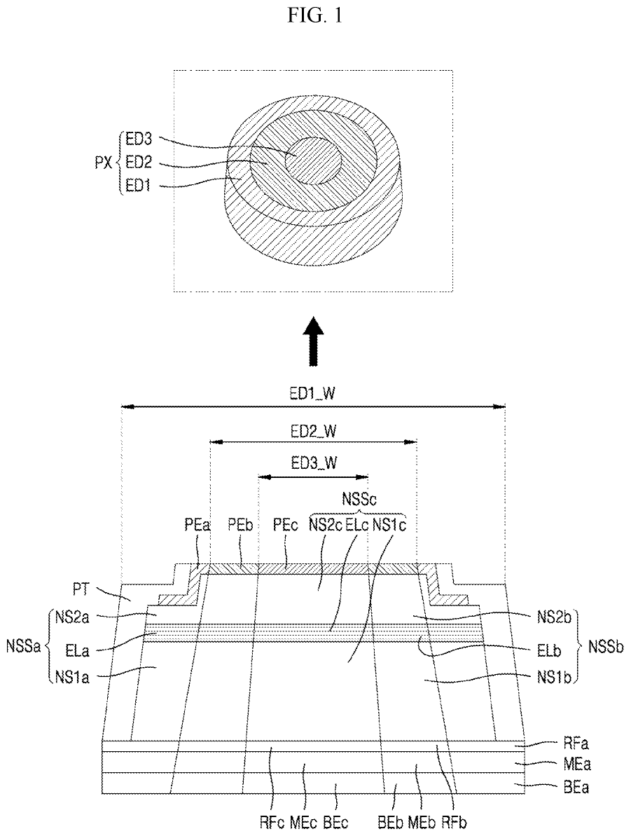

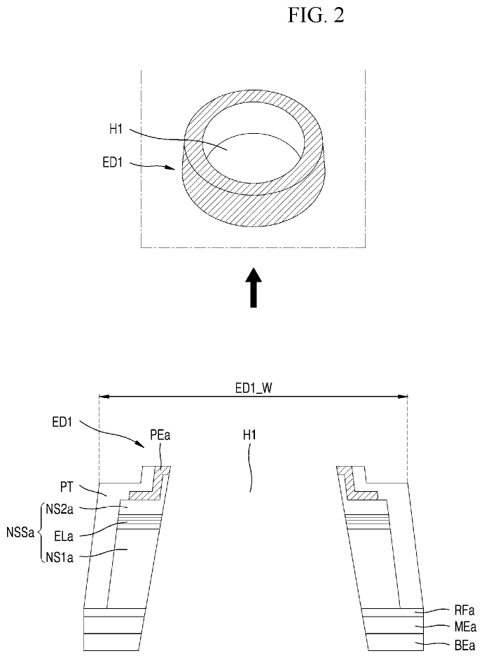

FIG. 1 is a diagram showing a display device according to an exemplary embodiment of the present disclosure. FIG. 2 to FIG. 4 are diagrams showing a structure of each light-emitting element.

Referring to FIG. 1, in a display device according to an exemplary embodiment of the present disclosure, a first light-emitting element ED1, a second light-emitting element ED2, and a third light-emitting element ED3 having different sizes may be assembled into one pixel PX. FIG. 1 shows a cross-sectional view of the entire pixel and above it, as indicated by the arrow, a partial isometric view of the upper section. Each of the light emitting elements ED1, ED2 and ED3 can be consider sub-pixels. For example, in one pixel PX, one or more ring-shaped light-emitting elements including through-holes extending therethrough may be assembled and arranged so as to overlap each other, and the first light-emitting element ED1, the second light-emitting element ED2, and the third light-emitting element ED3 having the different sizes may be disposed such that an outer circumferential surface of one element is in contact with an inner circumferential surface of another element. Accordingly, one pixel PX may have a circular shape, having each of the subpixels in the form of nested cylinders. In this regard, the first light-emitting element ED1 may emit red light, the second light-emitting element ED2 may emit green light, and the third light-emitting element ED3 may emit blue light.

In an embodiment of the present disclosure, the pixel in which the light-emitting elements emitting light of three colors, the first light-emitting element ED1, the second light-emitting element ED2, and the third light-emitting element ED3, are assembled and arranged so as to overlap each other is described, but the present disclosure is not limited thereto. For example, a light-emitting element emitting white light may be further included. One way to obtain white light is to have all three colors, red, blue and green emitted by the one pixel PX that is disclosed herein at the same time, which will result in white light from this pixel. Then, if light of a particular color other than white is desired to be emitted, a color filter can be positioned over the pixel to result in the emission of a desired color of light, whether red, green, blue or some other color.

When constituting the pixel PX with the first light-emitting element ED1, the second light-emitting element ED2, and the third light-emitting element ED3, the first light-emitting element ED1 and the second light-emitting element ED2 may have the ring shapes including the through-holes extending therethrough, respectively, and the third light-emitting element ED3 disposed at an innermost portion of the pixel PX may have a shape filling an empty space.

As an inside surface of one light-emitting element having the ring shape, like a doughnut and serves as a pocket, sleeve or enclosure for another light-emitting element, the pixel PX may be formed in a shape in which a light-emitting element disposed at an outer side surrounds a light-emitting element disposed at an inner side. The term pocket is used herein the broadest sense to include a sleeve, enclosure, doughnut or other enclosure that surrounds a part of the structure placed therein, but is not required to complete enclose or surround on all sides.

In the first light emitting element ED1, the second light emitting element ED2, and the third light emitting element ED3 having different sizes each other, a size of the first light emitting element ED1 may be the largest, and a size of the third light emitting element ED3 may be the smallest. The second light emitting element ED2 may have a size smaller than that of the first light emitting element ED and larger than that of the third light emitting element ED3.

For example, referring to FIG. 1, the first light-emitting element ED1 disposed at an outermost side may have the greatest magnitude of a first width ED1_W. Because the first light-emitting element ED1, which emits the red light to the outside, has a great decrease in efficiency compared to other colors when miniaturized, the first light-emitting element ED1 may have the greatest magnitude of the first width ED1_W. The meaning of the term width is used herein in the broadest sense herein to refer to the distance across the breath of an object, such as a diameter of a cylinder, cone, sphere, from side to side of a cube, trapezoid, pentagon or other area or volume being considered. If it is in the shape of cube, the edges and corners of the cube might be rounded.

The second light-emitting element ED2 disposed inside the first light-emitting element ED1 may have a magnitude of a second width ED2_W that is relatively smaller than the magnitude of the first width ED1_W of the first light-emitting element ED1. Accordingly, an inner surface of the first light-emitting element ED1 may be disposed in contact with an outer surface of the second light-emitting element ED2. Moreover, the third light-emitting element ED1 disposed inside the second light-emitting element ED2 may have a magnitude of a third width ED3_W smaller than the second width ED2_W of the second light-emitting element ED2. Accordingly, an inner surface of the second light-emitting element ED2 may be disposed in contact with an outer surface of the third light-emitting element.

The first light-emitting element ED1, the second light-emitting element ED2, and the third light-emitting element ED may have the same height. Accordingly, upper electrodes PEa, PEb, and PEc may be disposed on the same plane. Additionally, the bottom electrodes, BEa, BEb, and BEc and may be all disposed in the same plane. When a voltage that exceeds the threshold of that respective diode is applied between the respective upper electrode and the bottom electrode one acting as the anode, the other as the cathode, light is emitted from each of the respective active layers ELa, ELb and ELc.

In a case of a comparative art process in which one light-emitting element is assembled per one location, when forming an assembly substrate, it is standard to maintain a spacing between adjacent light-emitting elements. Accordingly, as at least three light-emitting elements are arranged on the same plane to constitute the pixel, thus there is a limit to how small a pixel can be reduced. For this reason, there is a difficulty in to use the comparative art structures and process in technology fields requiring high resolution and a large number of pixels in a specific area, for example, per square inch.

To solve this problem of the comparative art, in the embodiment of the present disclosure, the at least two ring-shaped light-emitting elements having the different sizes and including the through-holes therein are assembled so as to overlap each other to constitute one pixel PX, thereby realizing a relatively small pixel compared to that in the comparative art case in which the at least three light-emitting elements are arranged in the horizontal direction to constitute the pixel. For example, a size of one pixel entire PX may not be greater than the width of the outermost light-emitting element among the plurality of light-emitting elements.

Accordingly, there is an effect of improving pixel integration and increasing pixel density within a display device of the same size. As the pixel integration and density may be improved, there is a benefit of implementing a display device that may be applied in the fields requiring the high resolution.

Moreover, as the pixel integration and density is improved within the display device of the same size, a pixel with high efficiency and high luminance may be realized even at low power, which has an advantage of reducing power consumption.

Referring to FIG. 1 and FIG. 2 together, the first light-emitting element ED1 includes a ring shape in which a first through-hole H1, which is an empty space, is provided. The first light-emitting element ED1 may include a nitride semiconductor structure NSSa, a passivation pattern PT surrounding an outer side of the nitride semiconductor structure NSSa, and a first upper electrode PEa. The nitride semiconductor structure NSSa of the first light-emitting element ED1 may include a structure in which a first semiconductor layer NSla, an active layer ELa, and a second semiconductor layer NS2a are sequentially stacked from the bottom.

FIG. 2 shows a cross-sectional view of the first sub-pixel ED1, and above it, as indicated by the arrow, a partial isometric view of the upper section of the first sub-pixel ED1.

The first semiconductor layer NSla of the first light-emitting element ED1, as a layer for supplying electrons to the active layer ELa, may include a nitride-based semiconductor including a first conductivity-type impurity. For example, the first conductivity-type impurity may include an N-type impurity. The active layer ELa disposed on the first semiconductor layer NSla, as a layer for emitting light, may have a structure of a multi-quantum well (MQW) having a well layer and a barrier layer having a higher band gap than the well layer.

The second semiconductor layer NS2a is a layer that is formed on the active layer ELa to inject holes into the active layer ELa. The second semiconductor layer NS2a may include a nitride-based semiconductor including a second conductivity-type impurity. For example, the second conductivity-type impurity may include a P-type impurity. The active layer ELa may emit light from a combination of electrons and holes respectively supplied from the first semiconductor layer NSla and the second semiconductor layer NS2a.

A reflective metal layer RFa, a magnetic layer MEa, and a bonding electrode layer BEa may be sequentially disposed beneath the nitride semiconductor structure NSSa and the passivation pattern PT. The reflective metal layer RFa may be in contact with a rear surface of the first semiconductor layer NSla of the nitride semiconductor structure NSSa. The reflective metal layer RFa may reflect the light emitted when the light-emitting element emits light. The reflective metal layer RFa may contain a metal material with high reflectance. For example, the reflective metal layer RFa may contain silver (Ag) or aluminum (Al). The magnetic layer MEa may contain a magnetic material such that the first light-emitting element ED1 may be moved by a magnet during the self-assembly process to constitute the pixel, for example, it might contain cobalt, nickel or alloys thereof. The bonding electrode layer BEa may be disposed to fix the first light-emitting element ED1 on the substrate for the self-assembly.

The first light-emitting element ED1 may be disposed at the outermost portion of the pixel, and may have the greatest magnitude of the first width ED1_W.

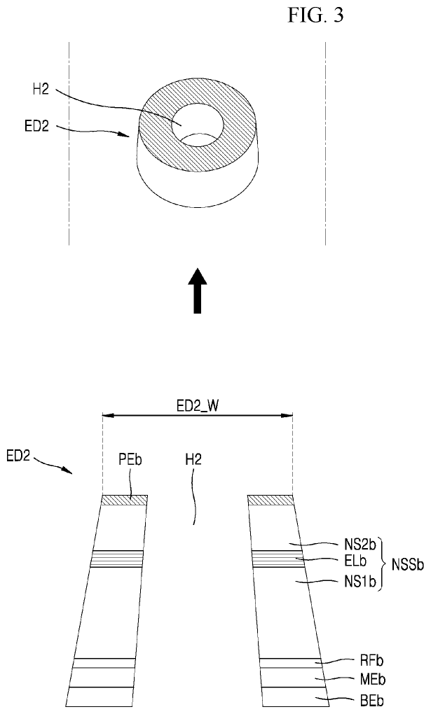

Referring to FIG. 1 and FIG. 3 together, the second light-emitting element ED2 includes a ring shape in which the second through-hole H2 is defined. The second light-emitting element ED2 may include a nitride semiconductor structure NSSb and a second upper electrode PEb. The nitride semiconductor structure NSSb of the second light-emitting element ED2 may include a structure in which a first semiconductor layer NS1b, an active layer ELb, and a second semiconductor layer NS2b are sequentially stacked from the bottom. In addition, a reflective metal layer RFb, a magnetic layer MEb, and a bonding electrode layer BEb may be sequentially disposed beneath the nitride semiconductor structure NSSb of the second light-emitting element ED2.

FIG. 3 shows a cross-sectional view of the second sub-pixel ED2, and above it, as indicated by the arrow, a partial isometric view of the upper section of the first sub-pixel ED2.

The first semiconductor layer NS1b, the active layer ELb, the second semiconductor layer NS2b, the reflective metal layer RFb, the magnetic layer Meb, and the bonding electrode layer BEb are respectively the same as the first semiconductor layer NSla, the active layer ELa, the second semiconductor layer NS2a, the reflective metal layer RFa, the magnetic layer MEa, and the bonding electrode layer BEa of the first light-emitting element ED1, so that descriptions thereof will be omitted.

The first light-emitting element ED1 disposed outwardly of the second light-emitting element ED2 may have the shape surrounding the second light-emitting element ED2 disposed at the inner side, and the second light-emitting element ED2 may have the magnitude of the second width ED2_W smaller than that of the first light-emitting element ED1.

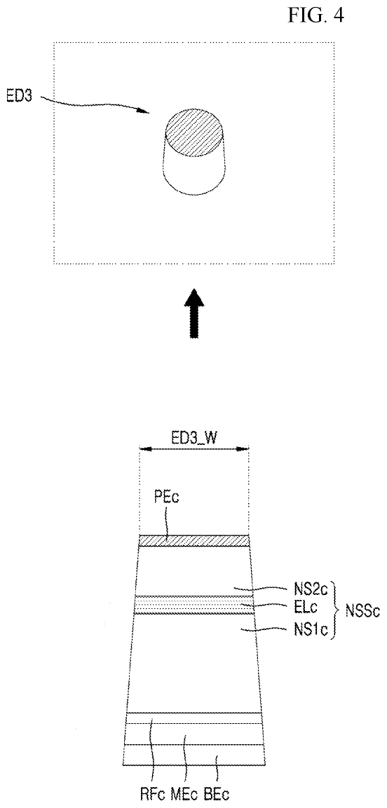

Referring to FIG. 1 and FIG. 4 together, the third light-emitting element ED3 may include a nitride semiconductor structure NSSc and a third upper electrode PEc. The nitride semiconductor structure NSSc of the third light-emitting element ED3 may include a structure in which a first semiconductor layer NS1c, an active layer ELc, and a second semiconductor layer NS2c are sequentially stacked from the bottom. In addition, a reflective metal layer RFc, a magnetic layer MEc, and a bonding electrode layer BEc may be sequentially disposed beneath the nitride semiconductor structure NSSc of the third light-emitting element ED3.

FIG. 4 shows a cross-sectional view of the third sub-pixel ED3, and above it, as indicated by the arrow, a partial isometric view of the upper section of the third sub-pixel ED3.

The first semiconductor layer NS1c, the active layer ELc, the second semiconductor layer NS2c, the reflective metal layer RFc, the magnetic layer MEc, and the bonding electrode layer BEc are respectively the same as the first semiconductor layer NSla, the active layer ELa, the second semiconductor layer NS2a, the reflective metal layer RFa, the magnetic layer MEa, and the bonding electrode layer BEa of the first light-emitting element ED1, so that descriptions thereof will be omitted.

The second light-emitting element ED2 disposed outwardly of the third light-emitting element ED3 may have the shape surrounding the third light-emitting element ED3 disposed at the inner side, and the third light-emitting element ED3 may have the magnitude of the third width ED3_W smaller than that of the second light-emitting element ED2.

As such, the first light-emitting element ED1, the second light-emitting element ED2, and the third light-emitting element ED3 having the different sizes may be assembled to constitute one pixel PX.

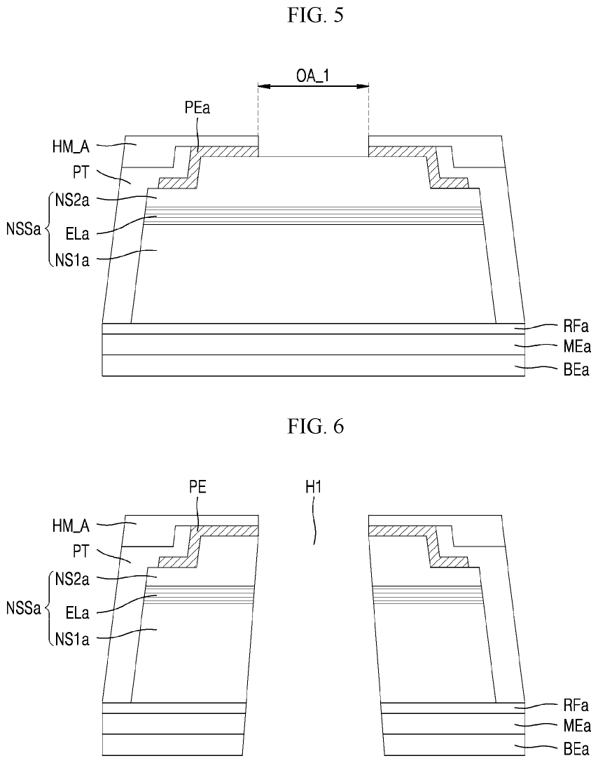

FIG. 5 to FIG. 7 are diagrams for illustrating a method for manufacturing a light-emitting element according to an exemplary embodiment of the present disclosure. Because a process of forming the second light-emitting element ED2 is the same as a process of forming the first light-emitting element ED1, in the present disclosure, the first light-emitting element ED1 is taken as an example for convenience of description.

Referring to FIG. 5, a light-emitting element structure is prepared. The light-emitting element structure may include the nitride semiconductor structure NSSa, the passivation pattern PT surrounding the outer side of the nitride semiconductor structure NSSa, and the first upper electrode PEa. The nitride semiconductor structure NSSa may include the structure in which the first semiconductor layer NSla, the active layer ELa, and the second semiconductor layer NS2a are sequentially stacked from the bottom.

The first upper electrode PEa may be disposed on the second semiconductor layer NS2a located at an uppermost portion of the nitride semiconductor structure NSSa. In addition, a hard mask pattern HM_A is disposed on the first upper electrode PEa. The hard mask pattern HM_A may include a first opening OA_1 exposing a portion of a surface of the second semiconductor layer NS2a by etching an exposed surface of the first upper electrode PEa. The light-emitting element according to an exemplary embodiment of the present disclosure may be a vertical semiconductor light-emitting element. When viewed from above, the hard mask pattern HM_A may have a shape surrounding the first opening OA_1. For example, the first opening OA_1 may have a circular shape. The entire structure may have the shape of a cylinder or of a truncated cone Cylinders have a circular shape cross-section or when viewed from the hope. While this is one acceptable shape for the pixel, it can also be in other shapes, or combinations thereof, including truncated cone, a truncated cone with an expanded base, a cube, which will have the shape of a rectangle from viewed from the side or top, a trapezoidal prism, a tetrahedron, a pyramid, octahedron or other platonic solid. The various shapes can be combined in a single structure.

Referring to FIG. 6, the nitride semiconductor structure NSSa, the reflective metal layer RFa, the magnetic layer MEa, and the bonding electrode layer BEa are sequentially etched using the hard mask pattern HM_A as an etch mask. Then, as the first opening OA_1 having the circular shape is etched, the first through-hole H1 may be defined in the nitride semiconductor structure NSSa.

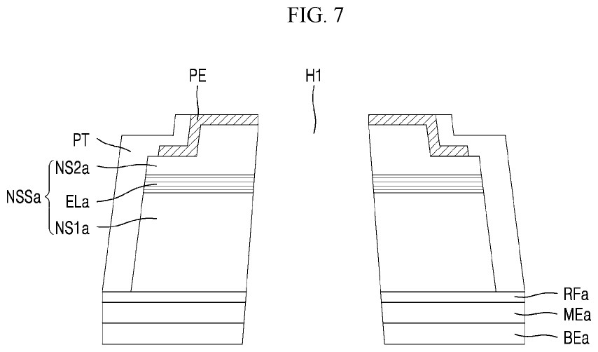

Referring to FIG. 7, the hard mask pattern HM_A is removed. Then, when viewed from above, the nitride semiconductor structure NSSa of the first light-emitting element may have a circular ring shape in which the first through-hole H1 is defined at a center.

The second light-emitting element ED2 may be formed by performing the same process as the process of forming the first light-emitting element ED1. Namely, the second light emitting element is formed in the hole H1 using the same steps used to form the first light emitting element ED1. In this regard, the second light-emitting element ED2 may have the relatively smaller diameter, in this instance ED2_W, than the first light-emitting element ED1. For example, the second light-emitting element ED2 may have a size at least similar to that of the first through-hole H1 defined in the first light-emitting element ED1. After the second light emitting element ED2 is fully formed, then a hole H2 is etched through it using the same process that was used for forming the hole H1. The third light-emitting element ED3 is then formed in this hole H2, which using the same process used to form hole H1. Moreover, the third light-emitting element ED3 may have the relatively smaller size than the first light-emitting element ED1 and the second light-emitting element ED2.

Hereinafter, a method for self-assembling the first light-emitting element ED1, the second light-emitting element ED2, and the third light-emitting element ED3 that are formed via the above-described method will be described.

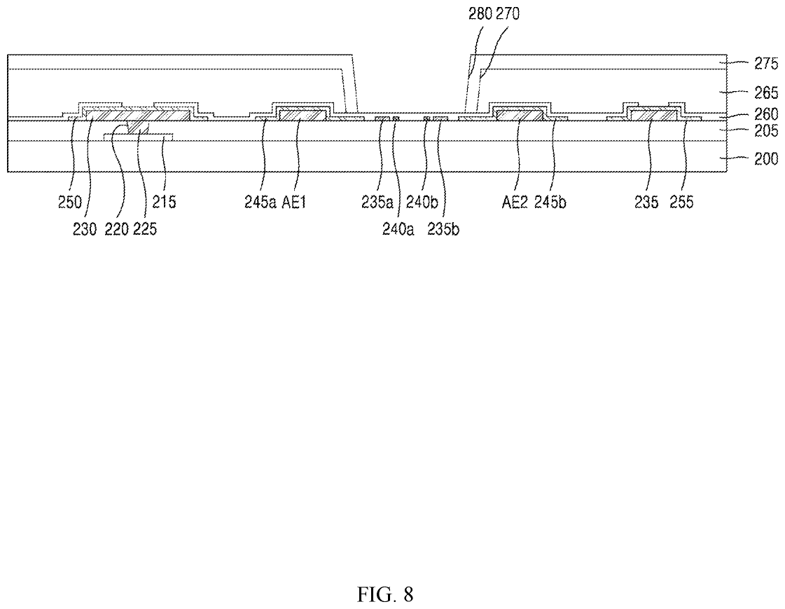

FIG. 8 to FIG. 16 are diagrams for illustrating a method for manufacturing a display device according to an exemplary embodiment of the present disclosure. In FIG. 8 to FIG. 16, circuit elements such as a thin-film transistor and a storage capacitor are which are present in the circuit are not shown for convenience of illustration.

Referring to FIG. 8, a substrate 200 for self-assembly is prepared. The circuit elements for driving the first to the third light-emitting elements ED1, ED2, and ED3 may be disposed on the substrate 200 for the self-assembly.

Specifically, a first protective layer 205 may be disposed on the substrate 200 for the self-assembly. Although not shown in the drawings, the thin-film transistor and capacitor may be disposed on the substrate 200 for the self-assembly. The thin-film transistor may supply a driving signal to drive the light-emitting element. The thin-film transistor may include a semiconductor layer, a gate electrode, and a gate insulating layer positioned between the semiconductor layer and the gate electrode. Moreover, the thin-film transistor may include a source/drain electrode connected to the semiconductor layer.

The first protective layer 205 may be formed to cover the thin-film transistor disposed thereunder. A connection electrode 215 may be disposed between the first protective layer 205 and the substrate 200 for the self-assembly. The connection electrode 215 may be electrically connected to the thin-film transistor, but may not limited thereto.

The first protective layer 205 may be formed to cover the connection electrode 215. A contact-hole 220 extending through the first protective layer 205 and exposing a portion of a surface of the connection electrode 215 may be defined. The contact-hole 220 may be filled with a conductive material or a metal material to form a contact electrode 225.

A plurality of signal lines 230 and 235 and assembly electrodes AE1 and AE2 may be disposed on the first protective layer 205. The assembly electrodes AE1 and AE2 may include a first assembly electrode AE1 and a second assembly electrode AE2.

The first assembly electrode AE1 and the second assembly electrode AE2 may be spaced apart from each other, and an electric field may be generated by applying a voltage to the first assembly electrode AE1 and the second assembly electrode AE2 in the self-assembly process.

The first assembly electrode AE1 and the second assembly electrode AE2 are covered with clad electrodes 245a and 245b, respectively. The clad electrodes 245a and 245b may include a first clad electrode 245a and a second clad electrode 245b, and may be disposed to cover the first assembly electrode AE1 and the second assembly electrode AE2, respectively.

The first clad electrode 245a and the second clad electrode 245b prevent or reduce corrosion of the first assembly electrode AE1 and the second assembly electrode AE2 in the self-assembly process in fluid, respectively, and then, allow the formation of the electric field for assembly of the first to the third light-emitting elements to be easily performed. For example, the first clad electrode 245a and the second clad electrode 245b may contain copper (Cu). A spacing between the first clad electrode 245a and the second clad electrode 245b is smaller than, for example, a spacing between the first assembly electrode AE1 and the second assembly electrode AE2, so that positions where the first to the third light-emitting elements are to be disposed within the assembly pocket may be fixed more precisely.

On the first protective layer 205, a pair of working electrodes 235a and 235b may be disposed on the same plane as the assembly electrodes AE1 and AE2, and disposed between the first assembly electrode AE1 and the second assembly electrode AE2. The pair of working electrodes 235a and 235b may include a first working electrode 235a and a second working electrode 235b. Moreover, another pair of working electrodes 240a and 240b may be disposed inwardly of the pair of working electrodes 235a and 235b. Another pair of working electrodes 240a and 240b may include a third working electrode 240a and a fourth working electrode 240b, and may be disposed between the first working electrode 235a and the second working electrode 235b.

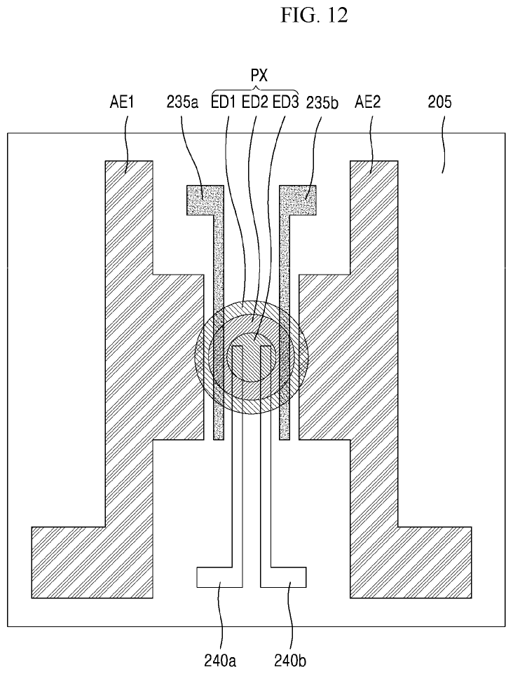

The assembly electrodes AE1 and AE2, the pair of working electrodes 235a and 235b, and another pair of working electrodes 240a and 240b may then serve as assembly electrode lines when assembling the first to the third light-emitting elements. Moreover, the assembly electrodes AE1 and AE2, the pair of working electrodes 235a and 235b, and another pair of working electrodes 240a and 240b may be connected to lower portions of the first to the third light-emitting elements and operate as lower electrodes corresponding to the upper electrodes PEa, PEb, and PEc. This will be described later with reference to FIG. 12.

A second protective layer 260 may be disposed on the first protective layer 205. The second protective layer 260 may contain an insulating material, and may be formed to cover the first and the second working electrodes 235a and 235b and the third and the fourth working electrodes 240a and 240b. The second protective layer 260 may include an open area exposing portions of surfaces of low-resistance electrodes 250 and 255 covering the plurality of signal lines 230 and 235.

A first planarization layer 265 and a second planarization layer 275 may be disposed on the second protective layer 260. The first planarization layer 265 may include an opening hole 270 corresponding to an area in which the first and second working electrodes 235a and 235b and the third and fourth working electrodes 240a and 240b are disposed. In addition, the second planarization layer 275 may include a self-assembly pocket 280. The self-assembly pocket 280 then serves to designate the positions where the first to the third light-emitting elements ED1, ED2, and ED3 are to be disposed. The self-assembly pocket 280 may be disposed corresponding to the area in which the first and second working electrodes 235a and 235b and the third and fourth working electrodes 240a and 240b are disposed.

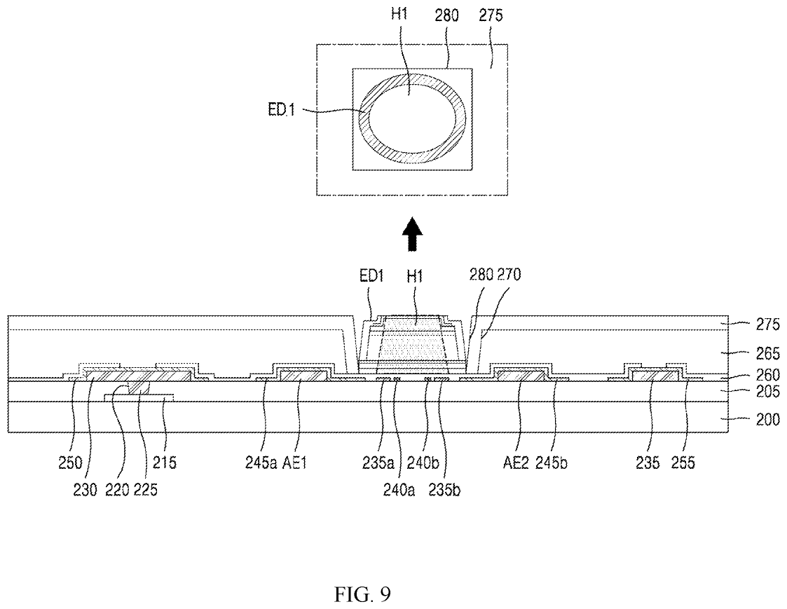

Referring to FIG. 9, the first light-emitting element ED1 is disposed on the self-assembly pocket 280. The first light-emitting element ED1 may be formed via the method described in FIG. 5 to FIG. 7. Accordingly, the first light-emitting element ED1 may include the first through-hole H1 therein. The first through-hole H1, which is the empty space located inside the first light-emitting element ED1, may correspond to the positions where the first and the second working electrodes 235a and 235b and the third and the fourth working electrodes 240a and 240b are disposed. Accordingly, the first light-emitting element ED1 is not electrically connected to the pair of working electrodes 235a and 235b and another pair of working electrodes 240a and 240b when the voltage for the self-assembly is applied on the substrate 200.

The first light-emitting element ED1 may be positioned on the assembly electrodes AE1 and AE2 by selectively applying voltage only to the assembly electrodes AE1 and AE2 by the configuration of applying the voltage to the assembly electrodes AE1 and AE2 of the substrate 200.

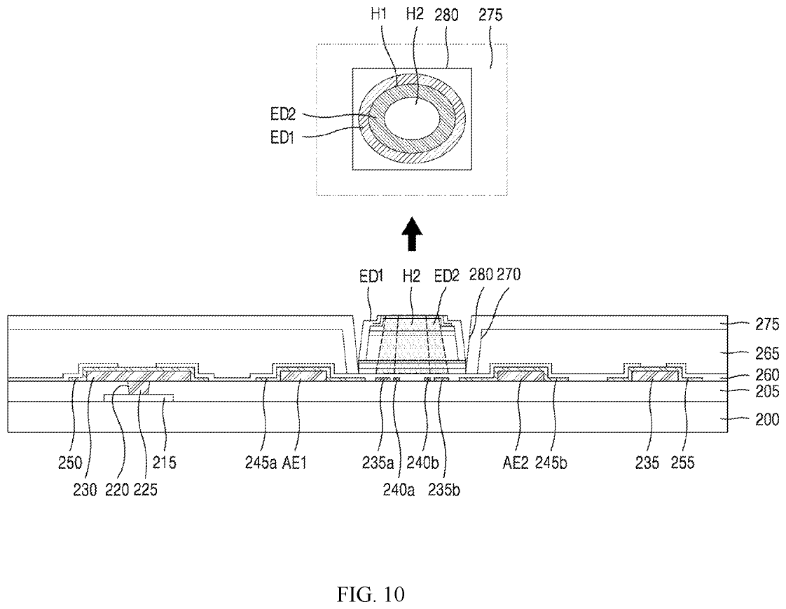

Referring to FIG. 10, the second light-emitting element ED2 is disposed on the self-assembly pocket 280. The second light-emitting element ED2 may be formed via the method described in FIG. 5 to FIG. 7. The second light-emitting element ED2 may be disposed within the first through-hole H1 (see FIG. 9), which is disposed inside the first light-emitting element ED1.

When a voltage is applied to disposed the second light-emitting element ED2 within the first through-hole H1 of the first light-emitting element ED1, the assembly electrodes AE1 and AE2, which served as the assembly voltages when assembling the first light-emitting element ED1, may act as fixed voltages, and the first and the second working electrodes 235a and 235b may act as assembly voltages. Accordingly, the first light-emitting element ED1 may be fixed while assembling the second light-emitting element ED2. In addition, as the second light-emitting element ED2 including the second through-hole H2 therein is disposed within the first through-hole H1 of the first light-emitting element ED1, the second through-hole H2 may be defined at an inner side. The inner surface of the first light-emitting element ED1 may be disposed in contact with the outer surface of the second light-emitting element ED2. The first through-hole H1 may serve as the sleeve or pocket in the self-assembly process.

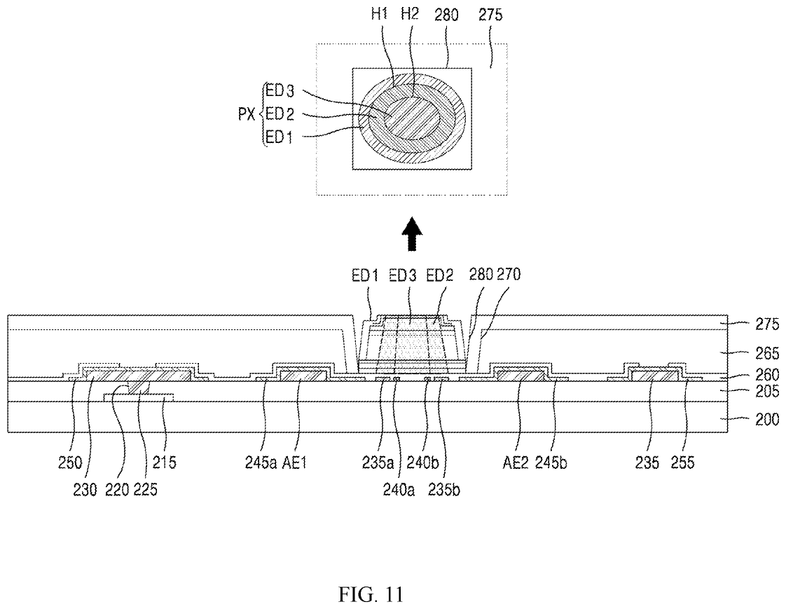

Referring to FIG. 11, the third light-emitting element ED3 is disposed on the self-assembly pocket 280. The third light-emitting element ED3 may be disposed within the second through-hole H2 defined inside the second light-emitting element ED2.

When a voltage is applied to dispose the third light-emitting element ED3 within the second through-hole H2 of the second light-emitting element ED2, the first and the second working electrodes 235a and 235b to which the assembly voltages are applied when assembling the second light-emitting element ED2 may act as fixed voltages, and the third and the fourth working electrodes 240a and 240b may act as assembly voltages. The first light-emitting element ED1 and the second light-emitting element ED2 may be fixed while assembling the third light-emitting element ED3. The inner surface of the second light-emitting element ED2 may be disposed in contact with the outer surface of the third light-emitting element ED2. As the third light-emitting element ED3 is disposed within the second through-hole H2 of the second light-emitting element ED2, the second through-hole H2 may serve as the pocket in the self-assembly process.

As the first light-emitting element ED1, the second light-emitting element ED2, and the third light-emitting element ED3 are sequentially assembled, the first light-emitting element ED1 may be disposed at the outermost portion, the second light-emitting element ED2 smaller than the first light-emitting element ED1 may be disposed inside the first light-emitting element ED1, and the third light-emitting element ED3 may be disposed inside the second light-emitting element ED2 to constitute one pixel PX. In one pixel PX according to the exemplary embodiment of the present disclosure, the ring shape may be repeatedly arranged in a central direction when viewed from a plane.

Referring to FIG. 12 showing a plan view in which the first and the second working electrodes 235a and 235b and the third and the fourth working electrodes 240a and 240b are arranged, the assembly electrodes AE1 and AE2 are disposed at outermost positions, and the first and the second working electrodes 235a and 235b and the third and the fourth working electrodes 240a and 240b are sequentially arranged inwardly of the assembly electrodes AE1 and AE2. For example, the first and second working electrodes 235a and 235b may be disposed so as to overlap the second light-emitting element ED2 and be electrically connected thereto. Accordingly, the first and the second working electrodes 235a and 235b may serve as a second lower electrode corresponding to the second upper electrode PEb of the second light-emitting element ED2.

The third and fourth working electrodes 240a and 240b disposed at innermost positions may overlap and be electrically connected to the third light-emitting element ED3 disposed at the innermost portion of the pixel PX. Accordingly, the third and the fourth working electrodes 240a and 240b may serve as a third lower electrode corresponding to the third upper electrode PEc of the third light-emitting element ED3.

Accordingly, process steps for forming the lower electrodes of the respective first to third light-emitting elements ED1, ED2, and ED3 may be omitted, thereby realizing process optimization.

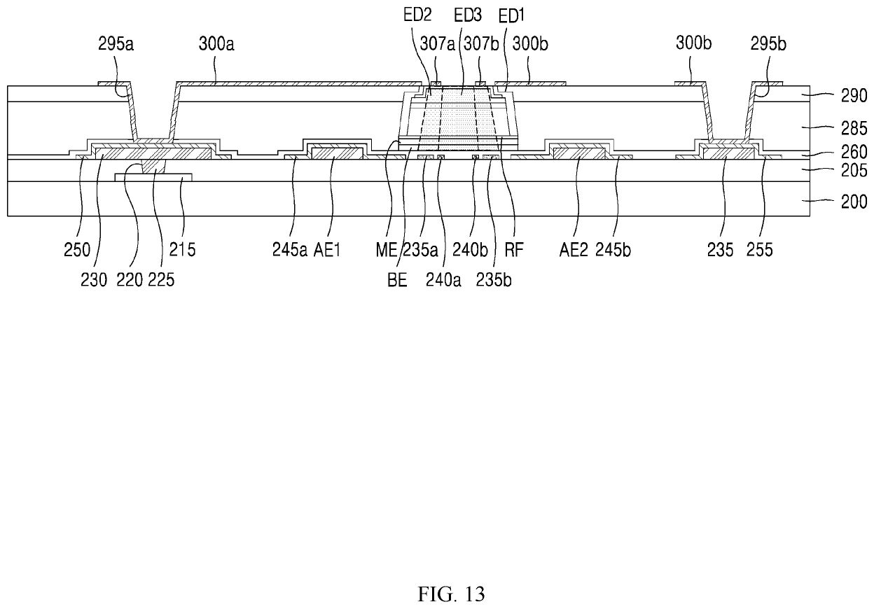

Referring to FIG. 13, after removing the first planarization layer 265 and the second planarization layer 275, a third planarization layer 285 and a fourth planarization layer 290 are sequentially formed. The fourth planarization layer 290 may have a relatively smaller thickness than that of the third planarization layer 285. The third planarization layer 285 and the fourth planarization layer 290 may be formed to have thicknesses the same as heights of upper surfaces of the first to the third light-emitting elements ED1, ED2, and ED3. Then, opening holes 295a and 295b that extend through the third planarization layer 285 and the fourth planarization layer 290 and expose portions of surfaces of the low-resistance electrodes 250 and 255 covering the plurality of signal lines 230 and 235 may be defined. The opening holes 295a and 295b may include a first opening hole 295a and a second opening hole 295b defined at both sides with the pixel PX interposed therebetween.

A first line electrode 300a, a second line electrode 300b, a third line electrode 307a, and a fourth line electrode 307b may be disposed along exposed surfaces of the first opening hole 295a and the second opening hole 295b. The first line electrode 300a, the second line electrode 300b, the third line electrode 307a, and the fourth line electrode 307b may be disposed on the same plane. The first line electrode 300a, the second line electrode 300b, the third line electrode 307a, and the fourth line electrode 307b may be formed together via one patterning process.

The first line electrode 300a and the second line electrode 300b may be connected to the first light-emitting element ED1 and electrically connected to the upper electrode of the first light-emitting element ED1. The third line electrode 307a and the fourth line electrode 307b may be electrically connected to the upper electrode of the second light-emitting element ED2.

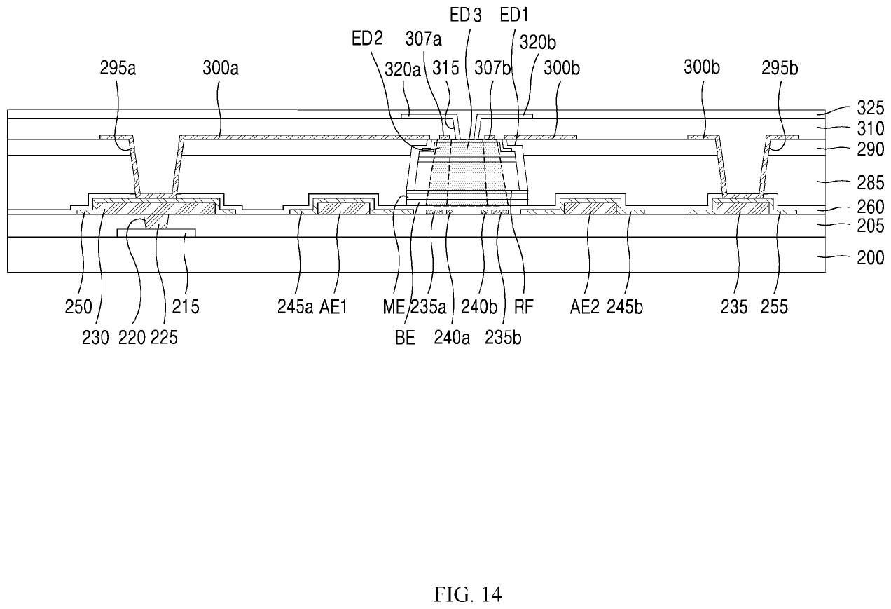

Referring to FIG. 14, a fifth planarization layer 310 is formed on the fourth planarization layer 290 on which the plurality of line electrodes 300a, 300b, 307a, and 307b are disposed. The fifth planarization layer 310 defines a third opening hole 315 therein for exposing a surface of the third light-emitting element ED3. Then, line electrodes 320a and 320b of the third light-emitting element ED3 are formed on the third opening hole 315. In addition, a sixth planarization layer 325 is formed on the line electrodes 320a and 320b and the fifth planarization layer 310. The line electrodes 320a and 320b may include a fifth line electrode 320a and a sixth line electrode 320b.

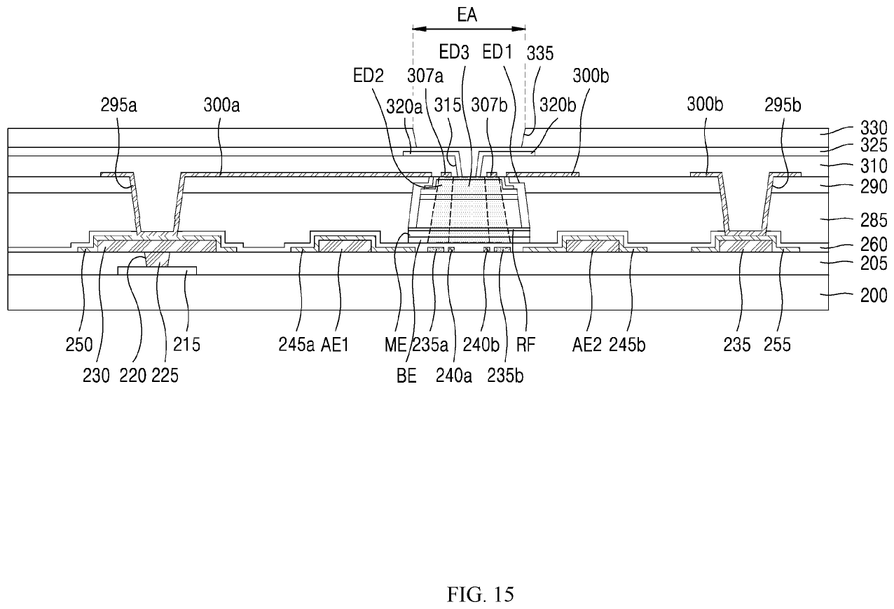

Referring to FIG. 15, a black matrix layer 330 including an opening 335 exposing a light-emitting area EA corresponding to the pixel including the first to the third light-emitting elements ED1, ED2, and ED3 is formed on the sixth planarization layer 325.

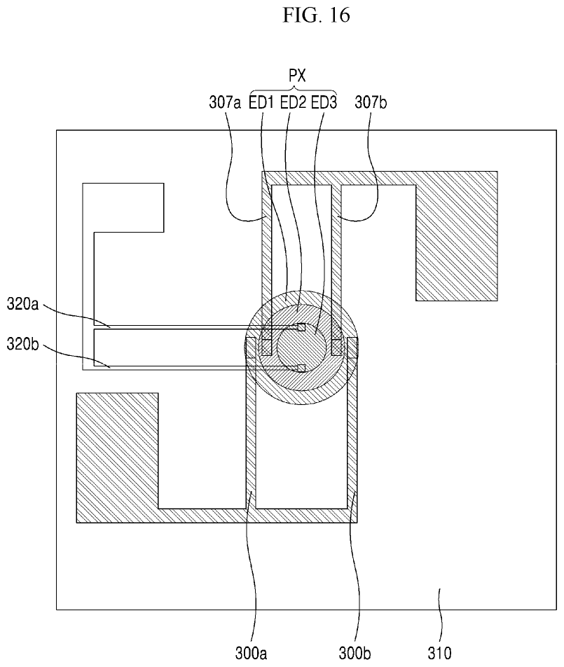

Referring to FIG. 16, each of the line electrodes disposed in the display device according to the exemplary embodiment of the present disclosure may be connected to each of the first light-emitting element ED1, the second light-emitting element ED2, and the third light-emitting element ED3 constituting the pixel PX. For example, the first line electrode 300a and the second line electrode 300b may be disposed in one direction overlapping the first light-emitting element ED1, and the third line electrode 307a and the fourth line electrode 307b may be disposed in one direction overlap the second light-emitting element ED2. In addition, the fifth line electrode 320a and the sixth line electrode 320b may be disposed to overlap the third light-emitting element ED3.

A data voltage can be selectively applied between the working electrodes AE, 235 and 240 coupled to the bottom electrodes and the line electrodes 300, 307 and 320 coupled to the upper electrodes according to image data desired from the drive transistor in the substrate 200 to cause light of a selected color and intensity to be emitted from one or more of the subpixels that make up the pixel PX.

In the embodiment of the present disclosure, the one or more ring-shaped light-emitting elements having the different sizes and including the empty spaces therein may be assembled so as to overlap each other to constitute one pixel. Because the relatively small-sized pixel may be realized, the pixel integration may be improved. Accordingly, the display device that may be applied in the fields requiring the high resolution may be realized.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a plurality of light-emitting elements having different sizes and assembled to constitute a single pixel,
wherein at least two of the light-emitting elements have respective through-holes therein that are disposed overlapping each other within the single pixel.

2. The display device of claim 1, wherein the at least two of the light-emitting elements are ring shaped and have the respective through-holes penetrating each light-emitting elements.

3. The display device of claim 1, wherein the plurality of light-emitting elements having the different sizes include a first light-emitting element, a second light-emitting element, and a third light-emitting element,
wherein a size of the first light-emitting element is the largest and a size of the third light-emitting element is the smallest.

4. The display device of claim 3, wherein the first light-emitting element, the second light-emitting element, and the third light-emitting element emit light of different colors.

5. The display device of claim 4, wherein the first light-emitting element emits red light, the second light-emitting element emits green light, and the third light-emitting element emits blue light,
wherein a width of the first light-emitting element is greater than widths of the second light-emitting element and the third light-emitting element.

6. The display device of claim 4, wherein, in the pixel, the first light-emitting element is disposed at an outermost portion and the third light-emitting element is disposed inwardly of the second light-emitting element.

7. The display device of claim 4, wherein an inner surface of the first light-emitting element is disposed in contact with an outer surface of the second light-emitting element,
wherein an inner surface of the second light-emitting element is in contact with an outer surface of the third light-emitting element.

8. The display device of claim 4, the first light-emitting element, the second light-emitting element, and the third light-emitting element have the same height.

9. The display device of claim 1, wherein a size of the single pixel is not greater than a width of an outermost light-emitting element among the plurality of light-emitting elements.

10. The display device of claim 1, wherein the light-emitting element includes:
a nitride semiconductor structure having a first semiconductor layer, an active layer, and a second semiconductor layer stacked therein;
a passivation pattern surrounding an outer side of the nitride semiconductor structure; and
an upper electrode disposed on the second semiconductor layer,
wherein a reflective metal layer, a magnetic layer, and a bonding electrode layer are sequentially disposed on one surface of the first semiconductor layer not connected to the active layer, and the through-hole extends through the light-emitting element from the upper electrode to the bonding electrode layer.

11. The display device of claim 2, wherein the light-emitting element includes:
a nitride semiconductor structure having a first semiconductor layer, an active layer, and a second semiconductor layer stacked therein; and
an upper electrode disposed on the second semiconductor layer,
wherein a reflective metal layer, a magnetic layer, and a bonding electrode layer are sequentially disposed on one surface of the first semiconductor layer not connected to the active layer, and the through-hole extends through the light-emitting element from the upper electrode to the bonding electrode layer.

12. The display device of claim 3, wherein the third light-emitting element includes:
a nitride semiconductor structure having a first semiconductor layer, an active layer, and a second semiconductor layer stacked therein; and
a third upper electrode disposed on the second semiconductor layer,
wherein a reflective metal layer, a magnetic layer, and a bonding electrode layer are sequentially disposed on one surface of the first semiconductor layer not connected to the active layer.

13. The display device of claim 3, further comprising:
a first assembly electrode and a second assembly electrode disposed on both sides with the first light-emitting element interposed therebetween;
a first working electrode and a second working electrode overlapping a lower portion of the second light-emitting element and located between the first assembly electrode and the second assembly electrode; and
a third working electrode and a fourth working electrode overlapping a lower portion of the third light-emitting element and located between the first working electrode and the second working electrode.

14. A pixel comprising:
a first subpixel having a hole extending therethrough, the first subpixel having a first light emitting element of a first color; and
a second subpixel positioned in the hole of the first subpixel, the second subpixel having a second light emitting element of a second color.

15. The pixel of claim 14 further comprising:
a hole extending through the second subpixel; and
a third subpixel positioned in the hole of the second subpixel, the third subpixel having a third light emitting element of a third color.

16. A method of making a pixel comprising:
forming a first light emitting element having a first electrode, a second electrode and a light emitting layer positioned between the first electrode and the second electrode;
forming a hole fully through the first electrode, the second electrode and the light emitting layer;
forming a second light emitting element having a first electrode, a second electrode and a light emitting layer positioned between the first electrode and the second electrode, the second light emitting element being formed in the hole that extends fully though the first light emitting element.

17. The method of claim 16 further including:
positioning the pixel on a substrate having respective a first and a second drive signal electrode thereon;
electrically coupling each of the first electrodes of the first and second light emitting elements to the first and second drive signal electrodes; and
forming first and second line electrodes overlying the pixel and electrically connected to the respective second electrodes of the first and second pixels.

18. The method of claim 16, further including:
forming a hole fully through the first electrode, the second electrode and the light emitting layer of the second light emitting element;
forming a third light emitting element having a first electrode, a second electrode and a light emitting layer positioned between the first electrode and the second electrode, the third light emitting element being formed in the hole that extends fully though the second light emitting element.
